(19) United States
(12) Patent Application Publication
(10) Pub. No.: US 2026/0171753 A1
(43) Pub. Date: Jun. 18, 2026

(54) METHOD FOR MONITORING THE TRANSITION TEMPERATURE AND OPTOELECTRONIC DEVICE

(71) Applicant: ams-OSRAM International GmbH, Regensburg (DE)

(72) Inventors: Marco BAUER, Rohr i. NB (DE); Josip MARIC, Sinzing (DE); Tobias FRITSCH, Regensburg (DE); Christian GRADL, Regensburg (DE)

(21) Appl. No.: 18/710,621

(22) PCT Filed: Nov. 17, 2022
(86) PCT No.: PCT/EP2022/082350

§ 371 Date: May 16, 2024

(30) Foreign Application Priority Data
Nov. 22, 2021 (DE) 10 2021 130 538.1

(51) Int. Cl. H01S 5/068; H01S 5/00

(52) U.S. Cl. CPC H01S 5/06808; H01S 5/0028; H01S 5/06804

(57) ABSTRACT

A method for regulating a supply current of a plurality of first laser diodes of an optoelectronic device during its intended use, including operating the plurality of first laser diodes, which are arranged on a carrier substrate, with the supply current; during operation of the plurality of first laser diodes simultaneously energizing at least one second laser diode, which is identical to the first laser diodes, with a current below a laser threshold of the second laser diode, wherein the at least one second laser diode is thermally coupled to the plurality of first laser diodes via the carrier substrate; determining a voltage (V_{f}) drop across the at least one second laser diode; and controlling the supply current as a function of the voltage (V_{f}) drop across the at least one second laser diode.

### RELATED APPLICATIONS

The present application is a US National Stage Application of International Application PCT/EP2022/082350, filed on Nov. 17, 2022 claims priority under 35 U.S.C. § 119(a) and 35 U.S.C. § 365(b) from German patent application No. 10 2021 130 538.1 dated Nov. 22, 2021, the disclosures of which are hereby incorporated by reference into the present application.

### FIELD

Various embodiments of the present disclosure relate to methods for regulating a supply current of a plurality of first laser diodes of an optoelectronic device during its intended use, in particular as a function of a transition temperature determined in one of the plurality of first laser diodes. In addition, various embodiments of the present disclosure relate to optoelectronic devices with integrated monitoring of the transition temperature in the optoelectronic device during its intended use.

### BACKGROUND

Laser diodes must be operated with a current to emit laser light. Laser operation begins at a characteristic current in the direction of flow, the threshold current. Below this current, the laser diode emits non-coherent radiation similar to a light-emitting diode, but no laser light. Above the threshold current, the optical output power of the laser diode is strictly proportional to the impressed current. The frequency of the light emitted by the laser diode depends, among other things, on the material of the laser diode, the impressed pump current and the temperature, in particular the transition temperature, within the laser diode. Heating the laser diode, particularly in the area of its active zone, leads to wavelength changes. The shift can be around +0.25-0.3 nm/K, with the maximum radiation shifting to longer wavelengths when heated due to a re-duction in the band gap in the active zone.

One approach to counteracting such wavelength changes is to keep the bandwidth of the emitted light low during the intended use of the laser diode by stabilizing these parameters, in particular by stabilizing the temperature.

Another approach is to compensate for a wavelength shift by readjusting the current impressed on the laser diode so that it essentially emits light with the same wavelength spectrum during its intended use.

Currently, the wavelength shift of a laser diode is usually determined optically in order to draw conclusions about the transition temperature in the active zone of the laser diode. A spectrometer is usually used to optically measure the wavelength shift by means of which the wavelength shift is recorded during the intended use of the laser diode. The recorded wavelength shift can then be used to draw conclusions about the changing transition temperature in the active zone of the laser diode at a constant impressed current. However, measuring the temperature using the approach of optically determining the wavelength shift is slow, causes high costs and increases the size of the product comprising the laser diode due to the precise spectrometer required.

There is therefore a need to specify a method for operating a laser diode of an optoelectronic device which counteracts at least one of the aforementioned problems. There is also a need to specify a corresponding optoelectronic device.

### SUMMARY

Various embodiments of the present disclosure are directed to a laser diode array, in addition to first laser diodes, at least one additional second laser diode of identical construction to the first laser diodes, which is thermally coupled to the first laser diodes. The thermal coupling can be achieved, for example, by a common cathode connection of the first and the at least one second laser diode. The additional at least one second laser diode is operated with an independent constant load current below the threshold value (laser threshold) during intended operation of the first laser diodes in order to avoid self-heating and light emission of laser light. A voltage detector is used to determine the voltage drop across the at least one second laser diode, which can change due to heating of the first laser diodes and thus also of the thermally coupled second laser diode during operation of the first laser diodes. The current impressed on the first laser diodes is readjusted as a function of the voltage drop or voltage change determined across the at least one second laser diode in order to avoid a wavelength shift in the laser light emitted by the first laser diodes.

The thermal coupling ensures that the second laser diode behaves thermally at least essentially identically to the first laser diodes during operation of the first laser diodes. Due to the identical design of the second laser diode and the first laser diodes, the transition temperature in the second laser diode and thus also the transition temperature in the first laser diodes can be deduced from the voltage drop or the measured voltage change measured via the second laser diode. One reason for this is that the voltage drop across a laser diode decreases when the transition temperature in the laser diode increases.

The use of an additional second laser diode, which is identical to the first, can have the advantage that the measured voltage drop or the measured voltage change across the second laser diode can be determined during operation of the first laser diodes by means of a load-independent measurement. This is due to the fact that the additional second laser diode is operated with an independent constant load current below the laser threshold and only “interacts” with the first laser diodes via the thermal coupling, but is not under load like them.

Due to the load-independent measurement, the measurement of the voltage drop via the second laser diode can be easily calibrated and the measurement accuracy of the transition temperature in the second laser diode and thus also in the first laser diodes can be increased. When measuring the voltage drop via the first laser diodes, however, an additional circuit for measuring the voltage drop in high-frequency pulsed operation of the first laser diodes would cause problems and calibration of the measurement would be more difficult due to the dependence on the load current.

Contrary to the method of optically determining the wavelength shift and thus the increase in the transition temperature of a laser diode using a spectrometer, measuring the transition temperature via the voltage drop across the laser diode with a constant impressed current is a direct and therefore more accurate measurement method. Particularly in the case of a current impressed on the laser diode with a constant load current below the laser threshold, i.e. an essentially load-free state of the laser diode, a particularly accurate and interference-free measurement of the voltage drop, or change in the voltage drop, across the laser diode can be carried out with a changing transition temperature within the laser diode. In addition, such a measurement can be calibrated particularly easily.

According to at least one embodiment, a method for controlling a supply current of a plurality of first laser diodes of an optoelectronic device during its intended use comprises the steps of:
Operating the plurality of first laser diodes arranged on a carrier substrate with the supply current;
During operation of the plurality of first laser diodes, simultaneous energizing at least one second laser diode, which is identical in construction to the first laser diodes, with a current below a laser threshold of the second laser diode, the at least one second laser diode being thermally coupled to the plurality of first laser diodes via the carrier substrate;
Determining a voltage drop across the at least one second laser diode; and
Regulating the supply current as a function of the voltage drop determined across the at least one second laser diode.

The term “identical” can be understood in particular in such a way that the first laser diodes and the at least one second laser diode are manufactured using the same technology and in particular have been grown on the same wafer.

According to at least one embodiment, the step of determining the voltage drop across the at least one second laser diode comprises determining the transition temperature of at least one of the plurality of first laser diodes, in particular based on the determined voltage drop across the at least one second laser diode during the intended operation of the first laser diodes.

When the first laser diodes are operated as intended, they can heat up over time due to the current impressed on the first laser diodes. If the impressed current is constant, this leads to the laser diodes emitting laser light of a different, in particular longer, wavelength in correlation with the heating. By determining the transition temperature within the first laser diodes, the current impressed on the first laser diodes can be readjusted in the event of a possible wavelength shift so that they essentially emit light with the same wavelength spectrum despite heating during their intended use.

According to at least one embodiment, the step of energizing the at least one second laser diode is performed by means of a constant current source. For example, the constant current source can be formed by a current mirror which is designed to apply a particularly small current to the at least one second laser diode. During the determination of the voltage drop across the at least one second laser diode, however, the at least one second laser diode can also be operated in pulsed mode, which, for example, reduces the power consumption of the system.

According to at least one embodiment, the plurality of first laser diodes is operated in pulsed, in particular high-frequency pulsed mode. For example, the first laser diodes can be designed to provide uniform, high-frequency modulated laser light (flood illumination).

According to at least one embodiment, the step of determining the voltage dropped across the at least one second laser diode is performed at least once per emitted laser pulse of the first laser diodes. For example, the step of determining the voltage dropped across the at least one second laser diode can take place at the end of an emitted laser pulse of the first laser diodes, i.e. exactly once per emitted laser pulse.

According to at least one embodiment, however, the step of determining the voltage drop across the at least one second laser diode is performed several times during an emitted laser pulse of the first laser diodes. The frequency of the emitted laser pulses of the plurality of first laser diodes may in particular differ from the frequency of the measurement of the voltage drop across the at least one second laser diode. In particular, the frequency of the measurement of the voltage drop across the at least one second laser diode may correspond to a multiple of the frequency of the emitted laser pulses of the plurality of first laser diodes.

According to at least one embodiment, in particular in the event that the step of determining the voltage drop across the at least one second laser diode takes place several times during an emitted laser pulse of the first laser diodes, the voltage values of the voltage drop across the at least one second laser diode determined during an emitted laser pulse of the first laser diodes are integrated. In particular, the determined voltage values are integrated over the duration of an emitted laser pulse in order to also take into account a heating of the laser diode within the period from the start of the emitted light pulse to the end of the emitted light pulse. The supply current for the first laser diodes is then readjusted depending on the integrated voltage value. Alternatively, the mean value or the average of the determined voltage values can also be determined over the same period of time, from the start of an emitted light pulse to the end of an emitted light pulse, and the supply current for the first laser diodes can be readjusted as a function of the averaged voltage value.

According to at least one embodiment, the method further comprises operating the at least one second laser diode with a current above the laser threshold at a time prior to the step of operating the plurality of first laser diodes. In addition to the function of measuring the voltage drop across the second laser diode, the second laser diode may comprise an additional function such as emitting laser light at a time prior to the step of operating the plurality of first laser diodes. The at least one second laser diode may, for example, be operated in a pulsed manner for the purpose of this additional function. For example, several second laser diodes can be arranged on the carrier substrate, which are designed to emit laser light, e.g. to provide laser light for proximity detection or a proximity sensor. During the intended operation of the first laser diodes, however, this function can be deactivated, and the second laser diodes or at least one of them are used to determine a voltage drop with a constant impressed current.

According to at least one embodiment, the method further comprises the steps of:
Operating the at least one second laser diode with a second supply current at a time prior to the step of operating the plurality of first laser diodes;
During operation of the at least one second laser diode, simultaneously energizing at least one of the plurality of first laser diodes with a current below a laser threshold of the first laser diode;
Determining a voltage drop across the at least one first laser diode; and
Regulating the second supply current as a function of the voltage drop determined across the at least one first laser diode.

By such a method, it is possible to combine at least one first and at least one second laser diode which never emit laser light at the same time. At a time when the first laser diode is emitting laser light, the second laser diode can be used to monitor the laser light emitting first laser diode with respect to its transition temperature. At a time when the second laser diode emits laser light, on the other hand, the first laser diode can be used to monitor the laser light-emitting second laser diode with respect to its transition temperature.

However, it is also possible that the at least one second laser diode is not assigned an additional function, but is only used to determine a voltage drop with a constant impressed current.

According to at least one embodiment, the plurality of first laser diodes are operated at a higher current than the at least one second laser diode during the step of determining the voltage dropped across the at least one second laser diode. In particular, the first laser diodes are operated with a current that is at least a factor of 50 higher than the current impressed on the at least one second laser diode. For example, the at least one second laser diode can be operated with approx. 1% of the supply current for the first laser diodes, which for individual small VCSEL apertures corresponds approximately to a value of 1 mA and a value just below the laser threshold. For other laser diodes, however, this can also correspond to a value of approximately 500 mA. The current applied to the at least one second laser diode should be selected below the laser threshold so that no laser light is emitted and there is no thermal load on the at least one second laser diode. A particularly low current applied to the at least one second laser diode also means in particular that the power loss of the optoelectronic device is kept as low as possible. The current applied to the at least one second laser diode should therefore be as low as practicable.

An optoelectronic device, in particular with integrated monitoring of the transition temperature in the optoelectronic device during its intended use, comprises a first current source for the electrical supply of a plurality of first laser diodes, which are arranged on a carrier substrate, and at least one second laser diode of identical construction to the first laser diodes, which is also arranged on the carrier substrate and which is thermally coupled to the plurality of first laser diodes via the carrier substrate. Furthermore, the optoelectronic device comprises a second current source which is designed to apply a current below the laser threshold of the second laser diode to the at least one second laser diode, a voltage detector which is designed to detect the voltage drop across the at least one second laser diode, and a control circuit which is connected to the first current source and the voltage detector and which is designed to control the first current source as a function of the voltage drop across the at least one second laser diode.

The first current source is designed to operate the first laser diodes with the supply current mentioned in the method, whereas the second current source can be formed by a constant current source already disclosed in the method, which is designed to supply the at least one second laser diode with a current below the laser threshold of the second laser diode.

According to at least one embodiment, the at least one second laser diode is arranged on the carrier substrate at a distance from the plurality of first laser diodes. In particular, the at least one second laser diode is arranged on the carrier substrate at a distance of at most 100 μm from at least one of the plurality of first laser diodes. This ensures that the at least one second laser diode behaves at least substantially identically due to the thermal coupling between the at least one second laser diode and the first laser diodes.

According to at least one embodiment, the plurality of first laser diodes and the at least one second laser diode have a common potential. In particular, the plurality of first laser diodes and the at least one second laser diode have a common cathode connection. This common cathode connection can, on the one hand, serve the thermal coupling and, on the other hand, enable simplified conductor routing on the carrier substrate.

According to at least one embodiment, the plurality of first laser diodes and the at least one second laser diode are each formed by a VCSEL (vertical-cavity surface-emitting laser) laser diode or by an EEL (edge-emitting laser) laser diode. The plurality of first laser diodes can, for example, form a VCSEL array, to which the at least one second laser diode is arranged adjacent on the carrier substrate. In the case of edge-emitting lasers, these can be designed as multi-channel components.

According to at least one embodiment, the plurality of first laser diodes is arranged in a first segment on the carrier substrate and the at least one second laser diode is arranged in a second segment on the carrier substrate. The plurality of first laser diodes and the at least one second laser diode may, for example, form a laser diode array and be arranged in rows and columns accordingly, wherein a first segment comprises the plurality of first laser diodes and a second segment comprises the at least one second laser diode. The first and second segments can have the same grid with the same spacing between the laser diodes, but the grid and the spacing between the laser diodes can also differ. It is also conceivable that the laser diodes within the segments are arranged randomly and without a recognizable grid on the carrier substrate.

According to at least one embodiment, the at least one second laser diode is formed by an additional segment on a VCSEL array that has a common cathode connection with the laser diodes of the VCSEL array. Such additional segments, or channels, which are only used specifically and only for a short time, are often already present in optoelectronic devices due to application requirements and can therefore be used to measure the transition temperature in the remaining laser diodes. For example, on high power VCSEL arrays, additional low power regions can be found for additional proximity measurement functions. This channel can then be used to measure the transition temperature of the high power laser. In addition, segmented VCSELs or multi-channel EELs are already known and can be easily modified in production. An additional segment or an additional channel for at least one second laser diode can therefore be easily implemented.

### BRIEF DESCRIPTION OF THE DRAWINGS

In the following, embodiments of the present disclosure are explained in more detail with reference to the accompanying drawings. They show, in each case schematically,

FIG. 1 a circuit diagram of an optoelectronic device according to some aspects of the proposed principle;

FIG. 2 a top view of an optoelectronic device according to some aspects of the proposed principle; and

FIG. 3 method steps of a method for regulating a supply current of a plurality of first laser diodes of an optoelectronic device according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principles of the present disclosure. Some aspects have a regular structure or shape. It should be noted that slight deviations from the ideal shape may occur in practice without, however, contradicting the concepts of the present disclosure.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

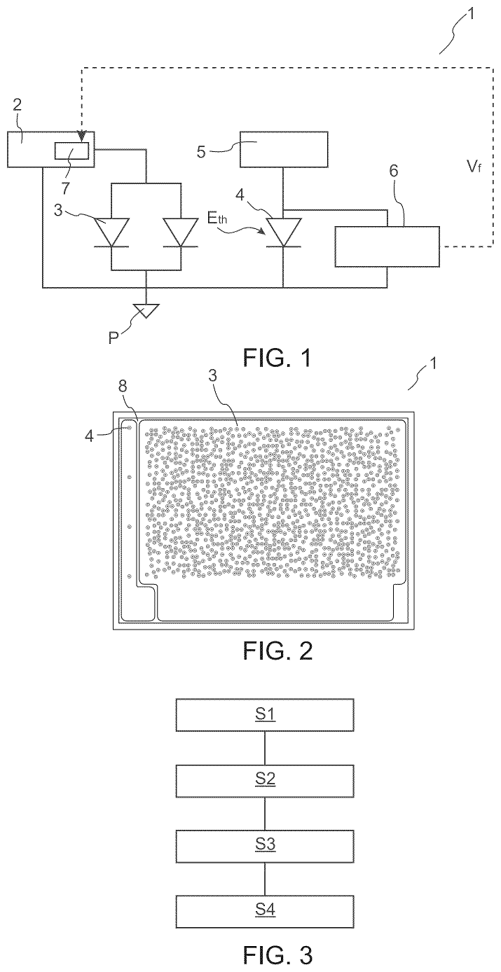

FIG. 1 shows a circuit diagram of an optoelectronic device 1 according to some aspects of the proposed principle. The opto-electronic device 1 comprises a regulated first current source 2 for the electrical supply of a plurality of first laser diodes 3, as well as a second laser diode 4 identical in construction to the first laser diodes 3, which is thermally coupled to the plurality of first laser diodes 3. The thermal coupling is indicated by the arrow (Eₜₕ) and can also be ensured not least by the fact that the first laser diodes 3 and the second laser diode 4 have a common potential P and, in particular, a common cathode connection by means of a thermally conductive material. Due to the thermal coupling, heating of the first laser diodes 3 during their intended operation leads to essentially identical heating of the second laser diode 4.

As an example, two first laser diodes 3 are shown in the circuit diagram, but the dots between the laser diodes ( . . . ) indicate that there can also be more than two first laser diodes 3. Furthermore, exactly one second laser diode 4 is shown in the circuit diagram as an example, but it can also be more than one second laser diode, which are connected in parallel with each other.

The optoelectronic device 1 also comprises a second current source 5, in particular a constant current source, which is designed to apply a current below the laser threshold of the second laser diode 4 to the second laser diode 4. By applying a current below the laser threshold to the second laser diode 4, the voltage drop V_{f} across the second laser diode can be determined by means of a voltage detector 6 by means of an essentially load-independent measurement. The voltage drop V_{f} across the second laser diode 4, or in particular a voltage change drop across the second laser diode 4, can be used to infer a temperature change, in particular a change in the transition temperature, in the second laser diode 4 at a constant current impressed on the second laser diode. The transition temperature determined in the second laser diode 4 can then in turn be used to infer the transition temperature in the first laser diode 3 on the basis of the thermal coupling. Due to the load-independent measurement, the measurement of the voltage drop across the second laser diode can be easily calibrated and the measurement accuracy of the transition temperature in the second laser diode and thus also in the first laser diodes can be increased.

By means of a control circuit 7, which is connected to the first current source 2 and the voltage detector 6, the first current source 2 can be controlled as a function of the voltage drop V_{f}or transition temperature determined via the second laser diode 4. Accordingly, the first current source 2 can be controlled or readjusted as a function of the voltage drop V_{f} determined across the second laser diode 4 in such a way that the first laser diodes 3 emit light with essentially the same wavelength spectrum despite heating during their intended use. A wavelength shift in the light emitted by the first laser diodes 3 due to heating of the same can thus be prevented.

Accordingly, the structure shown provides an optoelectronic device with integrated monitoring of the transition temperature in the optoelectronic device or in the second laser diode and thus also in the first laser diodes.

FIG. 2 shows a top view of an optoelectronic device 1 according to some aspects of the proposed principle. The optoelectronic device 1 comprises a carrier substrate 8 on which a plurality of first laser diodes 3 and four second laser diodes 4 are arranged. The first laser diodes 3 are arranged in the form of a first segment on the one carrier substrate 8 and the second laser diodes are arranged in the form of a second segment on the carrier substrate 8, which is adjacent to the first segment. The first and second channels or the first and second laser diodes 3, 4 have a common cathode connection, via which the first and second laser diodes 3, 4 are thermally coupled to one another, but they have different anode connections.

In the specific example, the first segment and therefore the first laser diodes 3 are a first channel of a 2-channel VCSEL array, which can also be referred to as a high-power channel and is designed to provide uniform, high-frequency modulated laser light (flood illumination). The second segment and thus the second laser diodes 4, on the other hand, is a second channel of the 2-channel VCSEL array, which can also be referred to as a low-power channel. The second channel is designed to emit light for proximity detection, for example, at a time when the first laser diodes 3 are out of operation, and to measure the transition temperature in the second or first laser diodes at a time when the first laser diodes 3 are emitting laser light.

FIG. 3 shows method steps of a method for controlling a supply current of a plurality of first laser diodes of an optoelectronic device during its intended use according to some aspects of the proposed principle. In a first step S1, the plurality of first laser diodes, which are arranged on a carrier substrate, are operated with the supply current. Simultaneously to step S1, in a second step S2, at least one second laser diode identical in construction to the first laser diodes is supplied with a current below the laser threshold of the second laser diode. The at least one second laser diode is thermally coupled to the plurality of first laser diodes via the carrier substrate, so that heating of the first laser diodes while they are emitting laser light also leads to heating of the at least one second laser diode. Simultaneously with the first and second steps S1, S2, the voltage drop across the at least one second laser diode is determined in a third step S3, which can change due to a heating of the first laser diodes and thus also of the at least one second laser diode during the intended use of the optoelectronic device. The supply current of the first laser diodes is then readjusted in a fourth step S4 as a function of the voltage drop determined across the at least one second laser diode, so that these emit essentially light with the same wavelength spectrum despite heating during their intended use.

### REFERENCE LIST

1 Optoelectronic device
2 First current source
3 First laser diode
4 Second laser diode
5 Second current source
6 Voltage detector
7 Control circuit
8 Carrier substrate
Eₜₕ Thermal energy
V_{f} Forward voltage
P Potential

What is claimed is:

1. A method for regulating a supply current of a plurality of first laser diodes of an optoelectronic device during its intended use, comprising:
operating the plurality of first laser diodes, which are arranged on a carrier substrate, with the supply current;
during operation of the plurality of first laser diodes simultaneously energizing at least one second laser diode, which is identical in construction to the first laser diodes, with a current below a laser threshold of the second laser diode, wherein the at least one second laser diode is thermally coupled to the plurality of first laser diodes via the carrier substrate;
determining a voltage drop across the at least one second laser diode; and
regulating the supply current as a function of the voltage drop determined across the at least one second laser diode.

2. The method according to claim 1, wherein determining the voltage drop across the at least one second laser diode comprises determining the transition temperature of at least one of the plurality of first laser diodes on the basis of the determined voltage drop.

3. The method according to claim 1, wherein energizing the at least one second laser diode is carried out by means of a constant current source.

4. The method according to claim 1, wherein the plurality of first laser diodes are operated in pulsed mode.

5. The method according to claim 4, wherein determining the voltage drop across the at least one second laser diode is carried out at least once per pulse of the first laser diodes.

6. The method according to claim 4, wherein determining the voltage drop across the at least one second laser diode is carried out at the end of a pulse of the first laser diodes.

7. The method according to claim 4, wherein determining the voltage drop across the at least one second laser diode is carried out a plurality of times during a pulse of the first laser diodes.

8. The method according to claim 7, wherein the voltage values of the voltage drop across the at least one second laser diode determined during a pulse of the first laser diodes are integrated and the supply current is regulated as a function of the integrated voltage value.

9. The method according to claim 1, further comprising operating the at least one second laser diode with a current above the laser threshold at a time prior to the step of operating the plurality of first laser diodes.

10. The method according to claim 1, wherein the plurality of first laser diodes are operated with a higher current than the at least one second laser diode during the step of determining the voltage drop across the at least one second laser diode, in particular with a current which is higher by at least a factor of 50.

11. An optoelectronic device with integrated monitoring of the transition temperature in the optoelectronic device during its intended use, comprising:
a plurality of first laser diodes arranged on a carrier substrate;
a first current source for the electrical supply of the plurality of first laser diodes;
at least one second laser diode of identical construction to the first laser diodes, which is arranged on the carrier substrate and which is thermally coupled to the plurality of first laser diodes via the carrier substrate;
a second current source which is configured to apply a current below the laser threshold of the second laser diode to the at least one second laser diode;
a voltage detector which is configured to detect a voltage drop across the at least one second laser diode; and
a control circuit, which is connected to the first current source and the voltage detector, and which is configured to control the first current source as a function of the voltage drop determined across the at least one second laser diode.

12. The optoelectronic device according to claim 11, wherein the at least one second laser diode is arranged at a distance from the plurality of first laser diodes on the carrier substrate and in particular at a distance of at most 100 μm.

13. The optoelectronic device according to claim 11, wherein the plurality of first laser diodes and the at least one second laser diode have a common potential.

14. The optoelectronic device according to claim 11, wherein the plurality of first laser diodes and the at least one second laser diode are each formed by a VCSEL laser diode or by an EEL laser diode.

15. The optoelectronic device according to claim 11, wherein the plurality of first laser diodes are arranged in a first segment on the carrier substrate and the at least one second laser diode is arranged in a second segment on the carrier substrate.
